(19) United States
(12) Patent Application Publication
(10) Pub. No.: US 2026/0362819 A1
(43) Pub. Date: Nov. 12, 2026

(54) CDTE BASED THIN FILM SOLAR CELL DEVICE WITH DIFFUSION BARRIER LAYER AND METHOD FOR MANUFACTURING THEREOF

(71) Applicants: China Triumph International Engineering Co., Ltd., Shanghai (CN); CTF Solar GmbH, Dresden (DE)

(72) Inventors: Shou PENG, Shanghai (CN); Liyun MA, Shanghai (CN); Xinjian YIN, Shanghai (CN); Ganhua FU, Shanghai (CN); Robert ARNDT, Dresden (DE); Marko SWOBODA, Dresden (DE)

(73) Assignees: China Triumph International Engineering Co., Ltd., Shanghai (CN); CTF Solar GmbH, Dresden (DE)

(21) Appl. No.: 19/120,816

(22) PCT Filed: Oct. 14, 2022
(86) PCT No.: PCT/CN2022/125288

§ 371 Date: Apr. 14, 2025

(51) Int. Cl. H10F 10/162; H10F 71/00; H10F 77/123

(52) U.S. Cl. CPC H10F 10/162; H10F 71/1253; H10F 77/1237

(57) ABSTRACT

A CdTe-based thin film solar cell device (10) and a manufacturing method thereof are provided. The CdTe-based thin film solar cell device (10) comprises a CdTe-based absorber layer (13) comprising a first partial layer (131) being selenium-rich CdTe layer, a second partial layer (133) having less selenium than the first partial layer (131), and a diffusion barrier layer (132) between the first partial layer (131) and the second partial layer (133). The diffusion barrier layer (132) has a larger band gap and a different crystal structure than the first partial layer (131). The manufacturing method comprises forming the CdTe-based absorber layer (131), which further comprises performing thermal treatment after depositing a first layer, a second layer and a third layer to form the first partial layer (131) from the first layer, the diffusion barrier layer (132) from the second layer and the second partial layer (133) from the third layer.

### FIELD OF THE INVENTION

The invention concerns a CdTe based thin film solar cell device comprising a diffusion barrier layer and a method for manufacturing such a solar cell device.

### BACKGROUND OF THE INVENTION.

In the state of the art, the CdTe based thin film solar cell has the following structure, wherein the layers are arranged in the mentioned sequence: a, transparent substrate, a transparent conducting oxide layer (TCO) formed as front contact layer; a cadmium telluride (CdTe) based absorber layer being the photoactive layer; and a back contact layer to collect the charge carriers. A p-n junction may be formed within the CdTe based absorber layer or between the CdTe based absorber layer and an adjacent layer, for instance a layer of the front contact or an additional layer, e.g. a window layer. The front contact layer, the absorber layer and the back contact layer each may be formed as a layer stack comprising different layers of different materials. All of these layers, in particular the absorber layer, are deposited under vacuum, using methods like CSS (closed space sublimation) or sputtering. After depositing the absorber layer and before depositing the back contact layer in superstrate configuration or the front contact layer in substrate configuration, an activation step is performed, which is an additional heat-mediated and chlorine-activated treatment step.

In recent years, the introduction of a selenium-rich layer toward the sunny side of CdTe based thin film solar cells has led to great improvements in the observed photoelectric conversion efficiencies of the solar cells. Alloys of CdTe containing selenium (Se) benefit from a reduced bandgap, which allows absorption of light with longer wavelengths than pure CdTe layers.

While the Se content of the solar cell can be varied during deposition of the absorber layer to achieve a desired gradient, other technologies rely on the deposition of multiple layers of material, for instance stacks of CdTe and CdSe or CdSeTe layers of varying thicknesses. During the activation step, recrystallization and diffusive flow of atomic species occurs, leading to a drift of Se-atoms away from their original position thereby forming Se-concentration gradients between the separate layers. However, these selenium atoms are only most useful, when concentrated in the region where light absorption actually occurs. Due to wavelength and typical penetration depth of visible light into CdTe absorber layers, it is sufficient for selenium to present only up to a depth of about 1000 nm within the absorber layer, which commonly has a thickness in the order of 3 μm to 4 μm. The depth is measured from the interface to the front contact layer in the thickness direction of the absorber layer. The large thickness of the whole absorber layer results from losses as can be found for a thinner absorber layer, in particular with respect to the electrical characteristics, e.g. open-circuit voltage and efficiency.

US 2014/0360565 A1 describes a CdTe based thin film solar cell with selenium, wherein the Se concentration at the light incident side of the absorber layer is larger than that at the back side of the absorber layer. The Se atomic concentration in the absorber layer varies in a range between 0.001 at % and 40 at %. The thin film solar cell is formed by depositing a Se source layer, e.g. a CdSeTe layer with a thickness of 500 nm, performing a CdCl₂ treatment at a temperature of higher than 400 °C, and subsequently depositing a CdTe layer with a thickness of 3.5 μm. Thereafter, a further CdCl₂ treatment at elevated temperature is performed.

Although US 2014/0360565 A1 describes that a top-hat profile of the Se-concentration profile provides an excellent efficiency of the solar cell in simulations, achieving such a profile is very difficult in reality. For real formed solar cell devices, US 2014/0360565 A1 describes a non-linear Se-concentration profile resulting from the diffusion of Se from the CdSeTe layer into the CdTe layer.

### SUMMARY OF THE INVENTION

It is an object of the invention to provide a CdTe based thin film solar cell device and a method of manufacturing such a device, wherein excessive selenium diffusion during the manufacturing process of the CdTe based thin film solar cell, in particular in a thermal treatment step like the activation step for vacuum-deposited CdTe comprising layers, is prevented.

The object is solved by a CdTe based thin film solar cell device and a method for manufacturing such a device according to the independent claims. Preferred embodiments are given in the dependent claims.

According to the invention, a CdTe based thin film solar cell device comprises at least a substrate, a front electrode on the substrate, a CdTe based absorber layer comprising selenium on the front electrode, and a back electrode on the CdTe based absorber layer. The CdTe based absorber layer comprises a first partial layer, a second partial layer, and a diffusion barrier layer arranged between the first partial layer and the second partial layer. The first partial layer is arranged on that side of the CdTe based absorber layer facing the front electrode and is a selenium-rich CdTe layer. The selenium content in the second partial layer is smaller than in the first partial layer. The first partial layer and/or the second partial layer may comprise further elements, for instance doping elements like Cl, P, As, Sb, V, Ag or Cu. The diffusion barrier layer is a layer having a band gap larger than the band gap of the first partial layer and a crystal structure differing from the crystal structure of the first partial layer. The band gap of the diffusion barrier layer is at least 0.2 eV larger than that of the first partial layer, wherein the difference in band gaps may preferably contribute entirely to the conduction band offset.

Due to its differing crystal structure, the diffusion barrier layer prevents or at least strongly reduces the diffusion of selenium atoms or selenium ions from the first partial layer to the second partial layer and allows a discontinuity of the selenium concentration or selenium content between the first partial layer and the second partial layer. That is, the selenium concentration at the interface of the first partial layer to the diffusion barrier layer may be several times higher than the selenium concentration at the interface of the second partial layer to the diffusion barrier layer, for instance 2 to 10 times, but also higher ratios are possible. In fact, an almost selenium-free second partial layer effectively having a selenium concentration or selenium content of zero (0) may be achieved in some embodiments.

Due to the diffusion barrier layer, selenium atoms or ions are concentrated in the region where light absorption actually occurs, i.e. in the first partial layer of the absorber layer being next to the front electrode and to a light-incident side of the solar cell. There, the positive effects of selenium within CdTe, in particular reduced bandgap and a greater photoelectric-conversion efficiency, show best, whereas selenium within the second partial layer, i.e. next to the back electrode and far away from the light-incident side of the solar cell, does not have a positive effect and therefore can be saved. Thus, not only the electrical characteristics of the solar cell are improved, but also costs may be saved and the long-term stability of the electrical characteristics of the solar cell is improved.

Furthermore, the diffusion barrier layer serves as an electron reflector which repels minority charge carriers. This is achieved by the band gap of the diffusion barrier material and a discontinuous bandgap jump at the interface of the first partial layer to the diffusion barrier layer. In particular, the band gap of the diffusion barrier material is higher than 1.5 eV which is at least 0.2 eV above the band gap of the first partial layer, and can be higher than the band gap of the second partial layer, but must not The bandgap jump results either from the differing crystal structure of the diffusion barrier material or its static structural composition, i.e. there is no graded composition or change of structural composition over the thickness of the diffusion barrier layer.

The first partial layer improves the photoelectric conversion efficiency of the impinging light due to the reduced band gap.

The second partial layer has positive effects on the electrical characteristics of the solar cell, like open-circuit voltage and fill factor, and comprises CdTe with large grains, i.e. grains in the dimension of 1500 nm to 3000 nm. The large grains reduce the number of grain boundaries and therefore reduce recombination of generated charge carriers on their path to the back electrode or to the front electrode.

The substrate is a transparent substrate, for instance made of glass. The front electrode is also essentially transparent. “Transparent” means that the material of the substrate or the front electrode, respectively, allows substantial transmission of at least some wavelengths of the impinging light through the substrate or the front electrode to the CdTe based absorber layer, wherein the transmitted wavelengths comprise at least a part of wavelengths absorbed by the material of the CdTe based absorber layer.

The front electrode usually comprises a transparent conductive material, e.g. a transparent conductive oxide (TCO) known to the skilled person. It may be a layer stack comprising different layers, like an antireflective layer and/or a buffer layer further to the TCO.

The back electrode usually comprises a conductive material, which may be transparent or opaque, e.g. a TCO or a metal as known to the skilled person. It may be a layer stack comprising different layers, like a metal and a buffer or transition layer.

In embodiments, the CdTe based thin film solar device additionally may comprise known intermediate layers, for instance between the substrate and the front electrode, between the front electrode and the absorber layer and/or between the absorber layer and the back electrode.

According to embodiments, the diffusion barrier layer comprises at least one layer made of a material selected out of the group comprising ZnTe, CdZnTe, C or a dielectric material or combinations thereof. The combination may be a layer stack comprising layers of different materials or may be a composition of different materials if applicable. A dielectric material suitable for the diffusion barrier layer may be, for instance, aluminium oxide (Al₂O₃), chromium oxide (Cr₂O₃), cadmium oxide (CdO), tellurium oxide (TeOₓ₎.

In embodiments, the diffusion barrier layer has a thickness in the range of 1 nm to 50 nm. The thickness of the diffusion barrier layer may depend on its material. That is, the diffusion barrier layer made of ZnTe or CdZnTe may have a thickness in the range of 20 nm to 50 nm, in particular in the range of 20 nm to 40 nm, whereas a diffusion barrier layer made of C or Al₂O₃ may have a thickness in the range of 1 nm to 30 nm, in particular in the range of 10 nm to 20 nm and more particularly in the range of 2 nm to 4 nm for Al₂O₃. The thickness is measured in any way along a direction from the front electrode to the back electrode.

In embodiments, the first partial layer is a CdSeₓTe₁₋ₓ layer with 0.1≤x≤0.4 and the second partial layer is a CdSeₓTe₁₋ₓ layer with 0≤x≤0.2. In any case, there is a difference between the selenium concentration in the first partial layer at the interface to the diffusion barrier layer and the selenium concentration in the second partial layer at the interface to the diffusion barrier layer, wherein the selenium concentration in the first partial layer is always higher than in the second partial layer. The ratio of the selenium concentration in the first partial layer at the interface to the diffusion barrier layer to the selenium concentration in the second partial layer at the interface to the diffusion barrier layer is, for instance, in the range of 2 to 10.

Furthermore, the selenium concentration within the first partial layer and/or within the second partial layer may have a gradient over the thickness of the respective layer. For example, the selenium concentration in the first partial layer may be greatest at the interface of the first partial layer to the front electrode and may then reduce linearly or non-linearly, e.g. the reduction may increase exponentially, over the thickness of the first partial layer into the direction towards the diffusion barrier layer. However, also other selenium concentration profiles within the first partial layer may be possible. Within the second partial layer, the selenium concentration may reduce over the thickness of the second partial layer linearly or non-linearly from the interface of the second partial layer to the diffusion barrier layer towards the interface of the second partial layer to the back electrode. In case the selenium concentration within the second partial layer is zero (0), it will be constantly zero. However, also other selenium concentration profiles within the second partial layer may be possible.

In embodiments, the first partial layer has a thickness in the range of 600 nm to 1200 nm, and the second partial layer has a thickness in the range of 1000 nm to 2500 nm. The thickness is measured in any way along a direction from the front electrode to the back electrode.

An overall thickness of the CdTe based absorber layer including the diffusion barrier layer lies in the range of 1.6 μm to 3.8 μm.

According to the invention, a method for manufacturing a CdTe based thin film solar cell device in superstrate configuration comprises at least the steps of providing a substrate, forming a front electrode on the substrate, forming a CdTe based absorber layer on the front electrode and forming a back electrode on the CdTe based absorber layer. The step of forming the CdTe based absorber layer at least comprises depositing a first layer on the front electrode, depositing a second layer on the first layer, depositing a third layer on the second layer, and performing a thermal treatment step after depositing the third layer.

The first layer comprises at least one layer comprising cadmium, tellurium and selenium or at least one layer comprising selenium and one layer comprising cadmium und tellurium. That is, the first layer may be a single layer formed of CdSeₓTe₁₋ₓ deposited, for instance, by co-deposition of Cd, Se and Te, or may be a layer stack comprising at least a selenium source layer, e.g. CdSe, and one layer of CdTe or any combination thereof. The subsequent deposition of at least one selenium source layer and at least one CdTe layer provides the advantage of better controlling the stoichiometry of a resulting first partial layer of the CdTe based absorber layer, i.e. the content and the concentration profile of selenium within the first partial layer. Furthermore, at least one layer of the first layer may comprise at least one further element, for instance a doping element, or the first layer may be a layer stack further comprising a doping source layer comprising at least one doping element. The doping element may be for instance like P, As, Sb, V, Zn, Ag or Cu, wherein the doping element may be present in elemental form, i.e. unbonded, or in a bonded form, e.g. as a salt.

The second layer is a diffusion barrier layer or a precursor layer of a diffusion barrier layer. A precursor layer of a diffusion barrier layer is a layer which is modified in structure or composition during following process steps of the inventive method for manufacturing a CdTe based thin film solar cell device such that a diffusion barrier layer is formed from the precursor layer. If, for instance the second layer is a ZnTe layer as a precursor layer, this layer may interact with neighbouring CdTe based layers and may be transformed into a CdZnTe layer. In embodiments, the composition of the second layer remains unchanged during further process steps, i.e. the second layer is already deposited as a desired diffusion barrier layer. In any case, the second layer and the resulting diffusion barrier layer is a layer of static structural composition over its thickness. What is meant by “diffusion barrier layer” is explained above with respect to the CdTe based thin film solar cell device according to the invention and will be explained again later.

The third layer comprises at least one layer comprising cadmium and tellurium, e.g. a CdTe layer. The third layer may comprise at least one further element, for instance a doping element, like P, As, Sb, V, Zn, Ag or Cu, or may be a layer stack further comprising a doping source layer comprising at least one doping element.

Some or all of the first, second and third layers may be deposited by vacuum deposition methods like sputtering, thermal evaporation or closed space sublimation (CSS). Furthermore, other deposition methods, like wet deposition, chemical deposition and others, may be used for depositing some of the layers, for instance the second layer or a selenium source layer or a doping source layer. The deposition conditions for the individual layers may be the same or may differ.

The thermal treatment step is performed at elevated temperatures, i.e. temperatures above 300 °C, and enables intermixing of layers, which may be comprised in the first or the third layer, and recrystallization of at least the third layer. Further, defects within the first, the second or the third layer or at the interfaces of one or more of these layers to a neighbouring layer may be reduced. Moreover, doping elements may diffuse or intermix with neighbouring layers resulting in doping of these layers.

At least as a result of the thermal treatment step, a first partial layer is formed from the first layer, a diffusion barrier layer is formed from the second layer in case of a precursor layer, and a second partial layer is formed from the third layer. “At least as a result of the thermal treatment step” means that some interactions of layers or re-compositions of the first and/or the second layer may occur already during deposition of the third layer.

The formed first partial layer is a selenium-rich CdTe layer, wherein the selenium content in the formed second partial layer is smaller than in the first partial layer. Forming the first and the second partial layer may include interaction of different layers of the first layer or the third layer, respectively. Thus, for instance, a CdSeₓTe₁₋ₓ layer may be formed from a selenium source layer and a CdTe layer by interdiffusion. Nevertheless, a CdSeₓTe₁₋ₓ layer deposited as the first layer or a CdTe layer formed as the third layer may also stay unchanged or, if a doping source layer was deposited, may only be doped with a doping element.

The diffusion barrier layer deposited as the second layer or formed from the second layer is a layer having a band gap larger than the bandgap of the first partial layer and a crystal structure differing from the crystal structure of the first partial layer. The second layer and/or the diffusion barrier layer formed from it serves as a diffusion barrier for selenium atoms or ions such that selenium atoms or ions essentially do not diffuse from the first layer or the first partial layer formed from it to the third layer or the second partial layer formed from it during the thermal treatment step. Even if the second layer is made of a material which interacts with the first and/or the third layer during the thermal treatment step, diffusion of selenium through it is essentially prevented. For example: The second layer made of ZnTe has a zinc-blende crystal structure, as do a CdTe layer. On the other hand, a CdSe layer has a wurtzite crystal structure. Therefore, ZnTe will more easily intermix with CdTe forming CdZnTe than with CdSe, thereby reducing or preventing the diffusion of selenium.

Forming a front electrode and forming a back electrode includes all known methods of depositing front and back electrode layers, for instance sublimation, evaporation, sputter deposition, wet deposition, chemical deposition and others.

In some embodiments, the method may also include deposition of intermediate layers known from state of the art, e.g. between the substrate and the front electrode, between the front electrode and the absorber layer as well as between the absorber layer and the back electrode. In superstrate configuration, the substrate is usually provided as a transparent substrate and the front electrode is formed as a transparent front electrode. Self-explanatory the front and back electrode may be deposited as layer stacks as known from state of the art. In further embodiments, the method may comprise an annealing step performed after depositing a back electrode material. This annealing step may comprise a thermal treatment and/or a light treatment, wherein the thermal treatment of the annealing step may be performed at a different temperature as compared to the thermal treatment step during formation of the CdTe based absorber layer, e.g. at temperatures in the range of 150 °C to 250 °C.

The method according to the invention provides the possibility for manufacturing a CdTe based thin film solar cell according to the invention. In particular, the method allows forming the absorber layer consisting of the selenium-rich first partial layer and the second partial layer having a smaller selenium content than the first partial layer, wherein a discontinuity of the selenium content between the first and the second partial layer is provided and conserved by the diffusion barrier layer arranged between the first and the second partial layers. Furthermore, the method widens the process window for depositing the third layer, i.e. the later second partial layer, and for the thermal treatment step or for further processing steps, like forming the back electrode. The process window for these process steps is widened in particular with respect to the used temperatures, since the diffusion barrier layer deposited as the second layer or formed from the precursor layer reduces or even inhibits the diffusion of selenium from the first layer or the first partial layer into the third layer or the second partial layer. Using higher temperatures, e.g. during deposition of the third layer or during thermal treatment, is beneficial in terms of grain growth, in particular within the third layer, and of defect healing within the absorber layer and at interfaces between the absorber layer and neighbouring layers. Furthermore, the process window for the mentioned steps may be widened with respect to the processing time, which allows, for instance, the deposition of a thicker third layer, i.e. a thicker second partial layer of the CdTe based absorber layer, or better results of defect healing or activation.

In embodiments, the second layer comprises at least one layer made of a material selected out of the group comprising ZnTe, CdZnTe, C or a dielectric material or combinations thereof. A dielectric material suitable for the diffusion barrier layer may be, for instance, aluminium oxide (Al₂O₃), chromium oxide (Cr₂O₃), cadmium oxide (CdO), tellurium oxide (TeOₓ).

In embodiments, the second layer is deposited with a thickness in the range of 1 nm to 50 nm. The thickness of the second layer depends on the material of the second layer. If, for instance, the second layer is made of ZnTe, which will interact with neighbouring CdTe layers and form CdZnTe, it may have a thickness in the range of 20 nm to 50 nm, in particular in the range of 20 nm to 40 nm, whereas a second layer made of C or Al₂O₃ may have a thickness in the range of 1 nm to 30 nm, in particular in the range of 10 nm to 20 nm and more particularly in the range of 2 nm to 4 nm for Al₂O₃.

In embodiments, the first layer is deposited such that the resulting first partial layer is a CdSeₓTe₁₋ₓ layer with 0.1≤x≤0.4 and the third layer is deposited such that the resulting second partial layer is a CdSeₓTe₁₋ₓ layer with 0≤x≤0.2, wherein the selenium concentration in the first partial layer is always higher than in the second partial layer. If the first layer is deposited as a CdSeₓTe₁₋ₓ layer alone, e.g. by co-sublimation of Cd, Se and Te, the selenium content in the deposition source is controlled corresponding to the desired selenium content in the first partial layer. If the first layer is a layer stack comprising a selenium source layer and a CdTe layer, the thicknesses of these layer and the content of selenium in the selenium source layer are controlled corresponding to the desired selenium content in the first partial layer. For example, the selenium source layer may be a CdSe layer with a first thickness and the CdTe layer is formed with a second thickness of three times the first thickness in order to get a first partial layer of CdSeₓTe₁₋ₓ with x=0.25. Furthermore, a plurality of selenium source layers and/or a plurality of CdTe layers may be deposited alternatingly, wherein the thicknesses of the individual layers and the sequence of the layers as well as the selenium content in the individual selenium source layers are controlled corresponding to the desired selenium content and a desired selenium concentration profile in the first partial layer. The same applies to the third layer respectively the second partial layer, wherein the third layer may even be a CdTe layer or CdTe based layer stack not comprising selenium at all.

In embodiments, the first layer is deposited with a thickness in the range of 600 nm to 1200 nm, and the third layer is deposited with a thickness in the range of 1000 nm to 2500 nm. For example, the first layer may be deposited as a CdSe layer having a thickness of 300 nm and a CdTe layer having a thickness of 900 nm.

In embodiments, a temperature of the substrate during depositing at least the third layer or during the thermal treatment is in the range of 400 °C to 650 °C, in particular in the range between 500 °C and 650 °C during depositing the third layer and in the range between 400 °C and 500 °C during the thermal treatment. In particular for thermal treatment performed as an activation treatment using an activation agent comprising chlorine, the mentioned temperature range is wider than in conventional manufacturing methods not using a second layer according to the invention, i.e. a diffusion barrier layer or a precursor layer of a diffusion barrier layer, within the absorber layer. In particular, higher temperatures may be used during thermal treatment, resulting in better forming large grains at least in the third layer respectively the second partial layer and in better defect healing within the absorber layer or at the interfaces of the absorber layer to neighbouring layers. The higher temperatures may be used without or at least with a reduced danger of selenium out-diffusion out of the first layer.

The duration of the thermal treatment step depends on the thicknesses of the individual layers of the first and the third layer as well as on the used temperature and may lie in some embodiments in the range of 5 minutes to 60 minutes, preferably in the range of 7 min to 25 min, and more preferably in the range of 10 min to 20 min.

In embodiments, the thermal treatment is performed as an activation treatment using an activation agent comprising chlorine. The activation agent may be deposited on the third layer or provided to the third layer using any technique known in the prior art. For instance, a liquid CdCl₂ may be applied to a surface of the third layer by spraying or roller coating followed by a temperature treatment in an oven or using a lamp. In particular, if using higher temperatures during the thermal treatment step, as described above, the chlorine ions will diffuse retarded within the absorber layer and the activation will perform with better results as compared to the state of the art. Subsequently to the thermal treatment step, a cleaning step may be performed in order to remove residuals of the activation agent from the surface of the third layer respectively the second partial layer.

Due to the activation treatment of the semi-finished CdTe based thin film solar cell device using an activation agent comprising chlorine, Cl may be introduced as a doping element into the CdTe based absorber layer, i.e. into the resulting first partial layer and/or the resulting second partial layer.

For realization of the invention, it is advantageous to combine the described embodiments and features of the claims as described above. However, the embodiments of the invention described in the foregoing description are examples given by way of illustration and the invention is nowise limited thereto. Any modification, variation and equivalent arrangement as well as combinations of embodiments should be considered as being included within the scope of the invention.

### BRIEF DESCRIPTION OF DRAWINGS

FIG. 1 shows schematically an exemplary embodiment of the layer structure of the CdTe based thin film solar cell device according to the invention.

FIG. 2 shows an exemplary selenium concentration profile of the CdTe based absorber layer of the CdTe based thin film solar cell device according to the invention.

FIG. 3 shows schematically a process sequence of an embodiment of the method for manufacturing a CdTe based thin film solar cell device according to the invention.

### REFERENCE NUMERALS

10 CdTe based thin film solar cell device
11 Substrate
12 Front electrode
13 CdTe absorber layer
131 First partial layer
132 Diffusion barrier layer
133 Second partial layer
14 Back electrode

### DETAILED DESCRIPTION

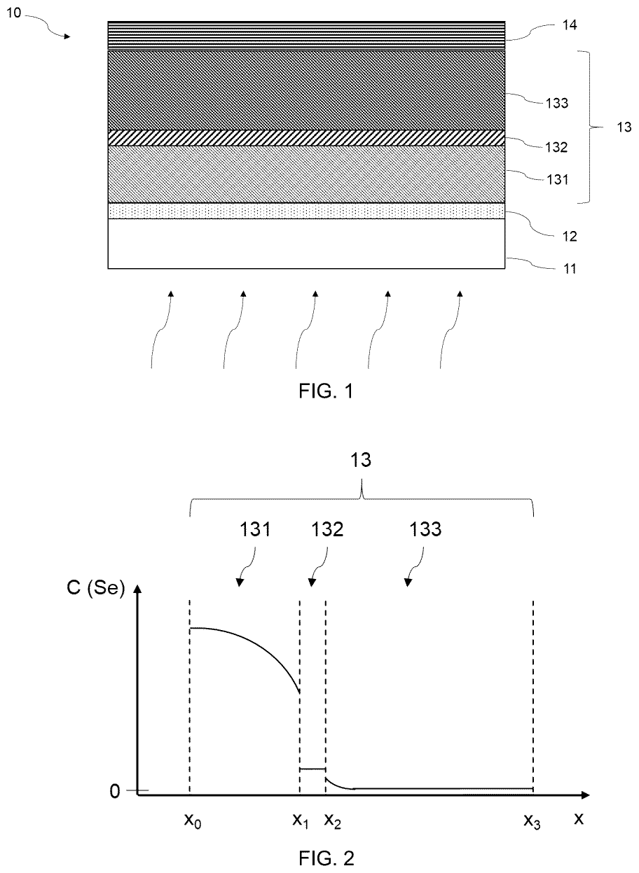

FIG. 1 schematically shows an exemplary embodiment of the layer structure of the CdTe based thin film solar cell device 10 according to the invention. The CdTe based thin film solar cell device 10 comprises a substrate 11, a front electrode 12, a CdTe based absorber layer 13 and a back electrode 14. The substrate 11 is made of glass and is a usually used substrate in the state of the art. The front electrode 12 is made of a TCO, e.g. SnO: F with a thickness of 400 nm. Nevertheless, the front electrode may also be a layer stack comprising different layers like diffusion barrier layers, conductive layers and others. The front electrode is formed at that side of the CdTe based thin film solar cell device 10 on which light impinges during operation of the CdTe based thin film solar cell device 10, the impinging light shown by arrows in FIG. 1. The back electrode 14 is a layer stack comprising a doped or undoped ZnTe layer in accordance to the state of the art with a thickness of 15 nm adjacent to the CdTe based absorber layer and a metal layer made of Mo and with a thickness of 350 nm on the ZnTe layer.

The CdTe based absorber layer 13 comprises a first partial layer 131, a diffusion barrier layer 132 and a second partial layer 133. The first partial layer 131 is a CdSeₓTe₁₋ₓ layer with x=0.35 and with a thickness of 1000 nm. The diffusion barrier layer 132 is made of Cd₁₋ₓZnₓTe with x=0.35 and has a thickness of 25 nm. The second partial layer 133 is a CdSeₓTe₁₋ₓ layer with x<0.01, wherein x gradually narrows from 0,05 near the interface to the diffusion barrier layer to 0 over the thickness of the layer, and with a thickness of 1500 nm. The given selenium content x is the summarized content over the whole thickness of the first or the second partial layer 131, 133, respectively, wherein the selenium concentration varies over the thickness of the respective layers as will be described with respect to FIG. 2.

FIG. 2 shows an exemplary selenium concentration profile of the CdTe based absorber layer 13 of the CdTe based thin film solar cell device of FIG. 1. The x-axis shows the position within the absorber layer 13, wherein X₀ is the position of the interface of the absorber layer 13, in particular the first partial layer 131, to the front electrode and X₃ is the position of the interface of the absorber layer 13, in particular the second partial layer 133, to the back electrode. X₁ is the position of the interface of the first partial layer 131 to the diffusion barrier layer 132 and X₂ is the position of the interface of the diffusion barrier layer 132 to the second partial layer 133. The c-axis shows the concentration of selenium within the absorber layer 13, however only in a relative size, i.e. without absolute values except of zero (0). As can be seen, the Se concentration is highest close to the front electrode, i.e. at X₀, wherein the Se concentration first slowly and later strongly decreases within the first partial layer 131 with the distance from the front electrode. However, the Se concentration is relatively high throughout the whole first partial layer 131 as compared to the Se concentration in the second partial layer 133. Even at the interface of the first partial layer 131 to the diffusion barrier layer 132, i.e. at X₁, the Se concentration is much higher than the highest Se concentration value in the second partial layer 133, e.g. 8 times higher. Though the Se concentration within the second partial layer 133 is highest at the interface of the second partial layer 133 to the diffusion barrier layer 132, i.e. at X₂, it is much lower than the Se concentration at X₁. That is, there is a discontinuity within the Se concentration profile between X₁ and X₂, and the Se concentration in the diffusion barrier layer 132 is lower than the Se concentration at X₁ and near the Se concentration at X₂. Nevertheless, the Se concentration in the diffusion barrier layer 132 may also be almost zero (0). Furthermore, although a constant Se concentration in the diffusion barrier layer 132 is shown in FIG. 2, the Se concentration may also have a gradient over the extension of the diffusion barrier layer 132 in other embodiments. The Se concentration in the second partial layer 133 very fast decreases with the distance from the diffusion barrier layer 132 to nearly zero (0). That is, the Se concentration within the second partial layer 133 is nearly zero throughout almost the whole thickness of the second partial layer 133 and in particular close to the back electrode.

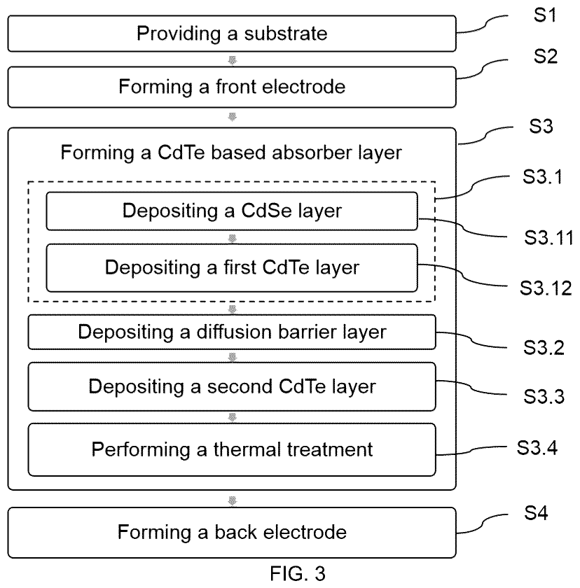

FIG. 3 schematically shows the process steps of an embodiment of the method for manufacturing a CdTe based thin film solar cell device as shown, for example, in FIG. 1. First, a substrate made of glass is provided (step S1). Next, a front electrode is formed onto the substrate in step S2, wherein the front electrode is a layer of SnO: F with a thickness of 400 nm which is deposited using CVD in accordance to the state of the art. Nevertheless, the front electrode may also be a layer stack comprising different layers like diffusion barrier layers, conductive layers and others.

In step S3, a CdTe based absorber layer is formed, wherein step S3 comprises four substeps S3.1 to S3.4 which will be explained in more detail in the following and which result in the CdTe based absorber layer stack described with respect to FIG. 1. In substep S3.1, a first layer is deposited on the front electrode, wherein this substep comprises two subsubsteps namely depositing a CdSe layer with a thickness of 300 nm on the front electrode (S3.11) and depositing a first CdTe layer with a thickness of 700 nm on the CdSe layer (S3.12) in the present embodiment of the method. In substep S3.2, a second layer, namely a diffusion barrier layer, is deposited on the first CdTe layer, wherein the diffusion barrier layer is a layer of CdZnTe with a thickness of 50 nm. In substep S3.3, a third layer, namely a second CdTe layer with a thickness of 1500 nm, is deposited on the diffusion barrier layer. All layers of substeps 3.1 to 3.3 are deposited using closed space sublimation (CSS), wherein the substrate temperature is held at 550 °C in all substeps S3.1 to 3.3. Subsequently to depositing all of the mentioned layers, a thermal treatment is performed in substep S3.4, wherein the semi-finished CdTe based thin film solar cell device comprising the substrate, the front electrode, the first layer, i.e. the CdSe layer and the first CdTe layer, the second layer, i.e. the diffusion barrier layer, and the third layer, i.e. the second CdTe layer, is held at a temperature of 500 °C for 30° minutes in air. In the result of the thermal treatment, the CdSe layer and the first CdTe layer of the first layer intermix and form a first partial layer of the CdTe based absorber layer. That is, the first partial layer of the CdTe based absorber layer is a CdSeₓTe₁₋ₓ layer with x=0.35 and with a thickness of 1000 nm. Further, the second CdTe layer, i.e. the third layer, recrystallizes due to the thermal treatment and forms a second partial layer of the CdTe based absorber layer. The second layer, i.e. the diffusion barrier layer, remains unchanged with respect to structural composition during the thermal treatment in substep S3.4.

Thermal treatment of substep S3.4 may be performed as an activation treatment using an activation agent like a chlorine-comprising compound, for instance CdCl₂. The activation treatment may comprise applying the activation agent onto the third layer, i.e. the second CdTe layer, by a wet chemical method or by vacuum evaporation, annealing in air atmosphere at a temperature of 430 °C, and removing residuals of the activation agent from the formed second partial layer after annealing.

Subsequently to step S3, i.e. to forming the CdTe based absorber layer, a back electrode is formed on the CdTe based absorber layer in step S4. Since the back electrode is a layer stack comprising a ZnTe layer adjacent to the CdTe based absorber layer and a metal layer made of Mo on the ZnTe layer, step S4 comprises depositing both mentioned layers on the CdTe based absorber layer by sputtering.

1. A CdTe based thin film solar cell device comprising at least
a substrate,
a front electrode on the substrate,
a CdTe based absorber layer comprising selenium on the front electrode, and
a back electrode on the CdTe based absorber layer,
wherein the CdTe based absorber layer comprises a first partial layer, a second partial layer, and a diffusion barrier layer arranged between the first partial layer and the second partial layer, the first partial layer being arranged on that side of the CdTe based absorber layer facing the front electrode and wherein the first partial layer is a selenium-rich CdTe layer and the selenium content in the second partial layer is smaller than in the first partial layer, and wherein the diffusion barrier layer is a layer having a band gap larger than that of the first partial layer and a crystal structure differing from the crystal structure of the first partial layer.

2. The CdTe based thin film solar cell device according to claim 1, characterized in that the diffusion barrier layer comprises at least one layer made of a material selected out of the group comprising ZnTe, CdZnTe, C or a dielectric material or combinations thereof.

3. The CdTe based thin film solar cell device according to claim 1 or 2, characterized in that the diffusion barrier layer has a thickness in the range of 1 nm to 50 nm.

4. The CdTe based thin film solar cell device according to any of claims 1 to 3, characterized in that the first partial layer is a CdSeₓTe₁₋ₓ layer with 0.1≤x≤0.4 and in that the second partial layer is a CdSeₓTe₁₋ₓ layer with 0≤x≤0.2.

5. The CdTe based thin film solar cell device according to any of claims 1 to 4, characterized in that the first partial layer has a thickness in the range of 600 nm to 1200 nm, and the second partial layer has a thickness in the range of 1000 nm to 2500 nm.

6. A method for manufacturing a CdTe based thin film solar cell device in superstrate configuration, comprising at least the steps of providing a substrate, forming a front electrode on the substrate, forming a CdTe based absorber layer on the front electrode and forming a back electrode on the CdTe based absorber layer,
wherein the step of forming the CdTe based absorber layer at least comprises:
depositing a first layer comprising at least one layer comprising cadmium, tellurium and selenium or at least one layer comprising selenium and one layer comprising cadmium und tellurium on the front electrode,
depositing a second layer being a diffusion barrier layer or a precursor layer of a diffusion barrier layer on the first layer,
depositing a third layer comprising at least one layer comprising cadmium and tellurium on the second layer, and
performing a thermal treatment step after depositing the third layer,
wherein a first partial layer is formed from the first layer, a diffusion barrier layer is formed from the second layer in case of a precursor layer and a second partial layer is formed from the third layer at least as a result of the thermal treatment step, the first partial layer being a seleniumrich CdTe layer, the selenium content in the second partial layer being smaller than in the first partial layer, and the diffusion barrier layer being a layer having a band gap larger than that of the first partial layer and a crystal structure differing from the crystal structure of the first partial layer.

7. The method according to claim 6, characterized in that the second layer comprises at least one layer made of a material selected out of the group comprising ZnTe, CdZnTe, C or a dielectric material or combinations thereof.

8. The method according to claim 6 or 7, characterized in that the second layer is deposited with a thickness in the range of 1 nm to 50 nm.

9. The method according to any of claims 6 to 8, characterized in that the first layer is deposited such that the resulting first partial layer is a CdSeₓTe₁₋ₓ layer with 0.1≤x≤0.4 and in that the third layer is deposited such that the resulting second partial layer is a CdSeₓTe₁₋ₓ layer with 0≤x≤0.2.

10. The method according to any of claims 6 to 9, characterized in that the first layer is deposited with a thickness in the range of 600 nm to 1200 nm, and the third layer is deposited with a thickness in the range of 1000 nm to 2500 nm.

11. The method according to any of claims 6 to 10, characterized in that a temperature of the substrate during depositing at least the third layer or during the thermal treatment is in the range of 400 °C to 650 °C for 5 min to 60 min.

12. The method according to any of claims 6 to 11, characterized in that the thermal treatment is performed as an activation treatment using an activation agent comprising chlorine.
